(19) United States
(12) Patent Application Publication
(10) Pub. No.: US 2007/0181900 A1
(43) Pub. Date: Aug. 9, 2007

(54) Semiconductor light emitting device and its manufacture method

(76) Inventors: Yoshiro Sato, Sapporo-shi (JP); Yoshiaki Yasuda, Meguro-ku (JP); Yoshihiro Nakamura, Meguro-ku (JP)

Correspondence Address: MASAO YOSHIMURA, CHEN YOSHIMURA, LLP, 1101 PENNSYLVANIA AVE. NW, 6TH FLOOR, WASHINGTON, DC, 20004, US

(21) Appl. No.: 11/655,265

(22) Filed: Jan. 19, 2007

(30) Foreign Application Priority Data
Jan. 19, 2006 (JP) 2006-010733

(51) Int. Cl. H01L 33/00; H01L 29/22; H01L 29/24

(52) U.S. Cl. 257/99; 257/101

(57) ABSTRACT

A semiconductor light emitting device is provided having a highly reliable reflection and electrode layer. The semiconductor light emitting device is manufactured by the steps of: forming an insulating film on a surface of a silicon substrate; forming an adhesion layer made of at least one of Ti and Cr on the insulating film; forming a barrier metal layer made of at least one of Ni, Pt and Pd on the adhesion layer; forming one or more silver alloy portions each constituting a silver alloy layer on the barrier metal layer; and electrically connecting at least one of the silver alloy portions to a semiconductor light emitting device chip.

### CROSS REFERENCE TO RELATED APPLICATION

This application is based on and claims priority of Japanese Patent Application No. 2006-010733 filed on Jan. 19, 2006, the entire contents of which are incorporated herein by reference.

### BACKGROUND OF THE INVENTION

A) Field of the Invention

The present invention relates to a light emitting device and its manufacture method, and more particularly, to a semiconductor light emitting device and its manufacture method.

B) Destruction of the Related Art

Semiconductor light emitting devices using LEDs are prevailing nowadays. The optical output efficiency and durability are required to be improved further. As an example of a semiconductor light emitting device, an LED package having a horn (concavity) formed by anisotropically etching a silicon (Si) wafer and deposited with metal films for supplying power to a light emitting diode chip is disclosed in Japanese Laid-Open patent application publication No. JP-A-2005-277380 and corresponding U.S. Application Publication No. US2006/0001055 A1, both of which are hereby incorporated by reference in their entirety. The metal film of the horn is used not only for power supply electrodes, but also for a reflection film for efficiently guiding light emitted from a light emitting diode to the upper exterior.

The reflection film is constituted of: an adhesion layer made of titanium (Ti), chromium (Cr) or the like and formed on a silicon dioxide (SiO₂) film formed on the surface of an Si wafer; a barrier layer formed on the adhesion layer and made of nickel (Ni), platinum (Pt) or the like for preventing gold (Au)—tin (Sn) eutectic bonding material or solder bonding material from diffusing into the Si wafer; and an uppermost metal layer made of silver (Ag), Au or the like and having a high reflectance. This reflection film can efficiently guide light fluxes from LEDs to the exterior.

### SUMMARY OF THE INVENTION

An object of this invention is to provide a semiconductor light emitting device having a reflection electrode having a high optical output efficiency and improved durability and a semiconductor light emitting device manufacture method.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, according to one aspect of the present invention, there is provided a semiconductor light emitting device comprising: a silicon substrate; one or more silver alloy portions each constituting a silver alloy layer formed over the silicon substrate; and a semiconductor light emitting diode chip electrically connected to the silver alloy portion, wherein the silver alloy portion forms a reflection surface.

According to another aspect of the present invention, there is provided a manufacture method for a semiconductor light emitting device comprising steps of: forming an insulating film on a surface of a silicon substrate; forming an adhesion layer made of at least one of Ti and Cr on the insulating film; forming a barrier metal layer made of at least one of Ni, Pt, and Pd on the adhesion layer; forming one or more silver alloy portions each constituting a silver alloy layer on the barrier metal layer; and electrically connecting at least one of the silver alloy portions to a semiconductor light emitting device chip.

According to another aspect of the present invention, there is provided a light emitting apparatus, including a light emitting device that emits light; a substrate; an adhesion layer on a surface of said substrate, the adhesion layer including at least one of titanium (Ti) and chromium (Cr); a barrier layer on the adhesion layer, the barrier layer including at least one of nickel (Ni), platinum (Pt), and palladium (Pd); and a reflection layer on the barrier layer to reflect at least a portion of said light emitted by said light emitting device, the reflection layer including silver (Ag) in an amount of about 94 atomic % or more, bismuth (Bi) in an amount of about 0.05 atomic % to about 0.15 atomic %, and neodymium (Nd) in an amount of about 0.1 atomic % to about 1.0 atomic %.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a graph showing reflectances of various metals relative to optical wavelengths.

FIG. 2A is a schematic diagram showing an LED package mounting an LED chip by using a flat plate type silicon submount, and FIG. 2B is a cross sectional view of the silicon submount.

FIG. 3 is a cross sectional view showing an example of the structure of an LED chip.

FIG. 4A is a schematic diagram showing an LED package mounting an LED chip by using a silicon submount with a horn, and FIG. 4B is a cross sectional view of the silicon submount with a horn.

FIGS. 5A to 5G-2 are cross sectional views and plan views illustrating manufacture processes of forming a horn without a ridge.

FIGS. 6A and 6B are graphs showing vertical reflectances of samples relative to a lapsed time.

FIG. 7 is a graph showing initial vertical reflectances of five types of Ag—Bi based alloy samples. FIG. 8 is a graph showing a dependency of a reflectance of Ag—Bi—Au upon an atmosphere pressure during film formation.

FIG. 9 is a graph showing reflectances of three kinds of samples.

FIG. 10 is a graph showing vertical reflectances of two kinds of metal film samples and a pure silver sample.

FIG. 11 is a graph showing reflectances of two kinds of metal films.

FIG. 12 is a schematic diagram showing a light emitting device using an LED package formed by an embodiment method of the present invention.

FIGS. 13A and 13B are plan views showing examples of other structures of a semiconductor light emitting device.

FIG. 14 is a cross sectional view showing another example of an LED chip mounting concavity formed in a silicon substrate.

### DESCRIPTION OF THE PREFERRED EMBODIMENTS

The material of a film constituting a reflector surface of a conventional LED package has been made of a metal having a high reflectance.

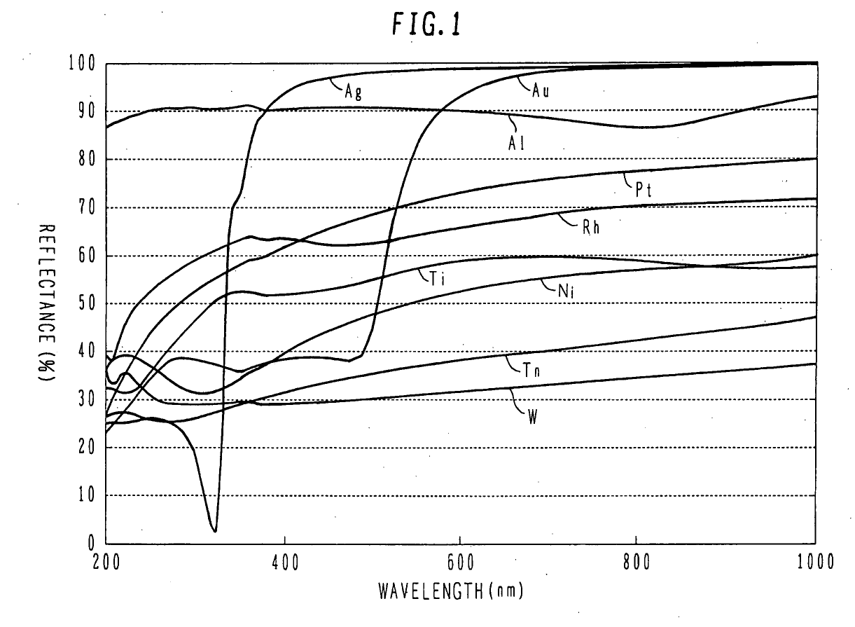

FIG. 1 is a graph showing reflectances of various materials relative to optical wavelengths. As shown in FIG. 1, Ag has the highest reflectance in the visible range and is used as the main reflection electrode material of an LED package.

However, the surface of a pure silver thin film is susceptible to oxidation and the like when it is exposed to the air for a long term at a high temperature and under high humidity, or the like. It is also likely to present phenomena such as growth of silver crystal grains and aggregation of silver atoms. These may result in degradation of conductivity, reduction in reflectance, and degradation of adhesion to a substrate.

The present inventors have researched and developed combinations of materials of a reflection layer, a barrier metal layer, and an adhesion layer between the barrier metal layer and a substrate, and the associated film forming methods. The present inventors have established a technology of using silver (Ag)—bismuth (Bi) based alloy having excellent durability as a reflection film material (as well as the material of a die bond electrode) for a semiconductor light emitting device. By adopting this technology, it becomes possible to use an appropriately designed Ag—Bi based alloy film formed on a horn (concavity) of a semiconductor light emitting device as a reflection film and as a die bond electrode and to improve an optical output efficiency of the semiconductor light emitting device. Because of a good durability performance of Ag—Bi based alloy, it is also possible to ensure higher reliability under high temperature and high humidity environments than in the case of using pure Ag or the like as in conventional cases.

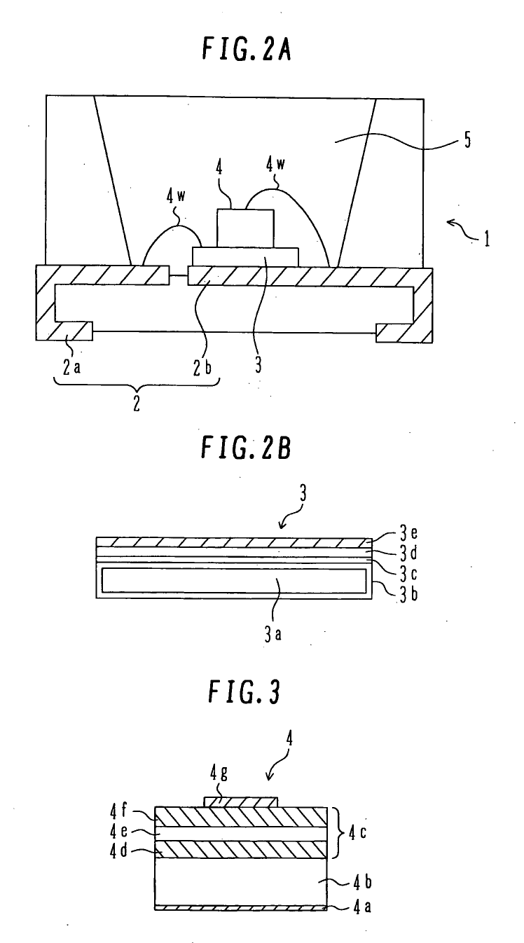

A semiconductor light emitting device according to an embodiment of the present invention will be described with reference to FIGS. 2A to 2B.

FIG. 2A is a schematic diagram showing an LED package of a semiconductor light emitting device which is mounting an LED chip by using a flat plate type silicon submount. As shown in FIG. 2A, a silicon submount 3 is die-bonded by silver paste to one lead 2b among two leads 2a and 2b of a lead frame 2 mounted in a resin housing 1. FIG. 2B is a cross sectional view of the silicon submount 3. A silicon substrate 3a is used as a substrate for forming the silicon submount 3. The surface of the silicon substrate 3a is planarized by optical polishing. First, a silicon dioxide film 3b as an insulating film is formed on the whole surface of the silicon substrate 3a by thermal oxidation in a diffusion furnace. The silicon dioxide film 3b ensures electrical insulation between the silicon submount 3 and lead 2b even if the silicon submount 3 is die-bonded to the lead 2b. Next, the following metal lamination layer is formed on the upper surface of the silicon substrate 3a covered with the silicon dioxide film 3b.

An adhesion layer 3c made of at least one of Ti and Cr is formed on the silicon substrate 3a covered with the silicon dioxide film 3b to provide for solid adhesion to the silicon dioxide film 3b. A barrier metal layer 3d for diffusion prevention made of at least one of Ni, Pt and palladium (Pd) is formed on the adhesion layer 3c. A silver alloy layer 3e as a reflection and electrode layer is formed on the barrier metal layer 3d. These layers are formed by sputtering or vapor deposition.

After the silicon submount 3 having the structure described above is die-bonded to the lead 2b, a semiconductor light emitting diode chip 4 is die-bonded to the silicon submount 3.

FIG. 3 shows an example of the structure of the semiconductor light emitting diode chip 4. For example, the semiconductor light emitting diode chip 4 is a monochromatic LED emitting substantially monochromatic color light of red (R), green (G) or blue (B). For example, a semiconductor layer of aluminum gallium arsenide (AlGaAs) is used for a red LED. A semiconductor layer of gallium phosphate (GaP) is used for a green LED. A semiconductor layer of gallium nitride (GaN) is used for a blue LED. For example, for the red LED, as shown in FIG. 3, a semiconductor layer 4c is formed on a substrate 4b of gallium arsenide (GaAs). The semiconductor layer 4c is a lamination of a p-type semiconductor layer 4d, an optical emission layer 4e and an n-type semiconductor layer 4f. Metal electrodes 4a and 4g are formed as lowermost and uppermost layers. For the green LED, a substrate of, e.g., GaP is used. Similar to the red LED, for the green LED, a semiconductor layer is laminated upon the GaP substrate, and metal electrodes are formed as lowermost and uppermost layers. For the blue LED, the structure is used which is disclosed, for example, in Japanese Patent Application No. JP-2005-167319 (Japanese Laid-Open Patent Application Publication No. 2006-344682), the entire contents of which are incorporated herein by reference.

By die-bonding the lower electrode 4a of the semiconductor light emitting diode chip 4 having the structure described above to the silicon submount 3, the silver alloy layer 3e of the silicon submount 3 and the lower electrode 4a can be electrically and mechanically bonded together. The silver alloy layer 3e of the silicon submount 3 and the lead 2a are wire-bonded to each other by using a wire 4w of gold or the like. The upper electrode 4g of the semiconductor light emitting diode chip 4 and the lead 2b are wire-bonded to each other by using a wire 4w of gold or the like. The inner space of the resin housing 1 is filled with resin 5 which is transparent or contains phosphor, to finish the LED package.

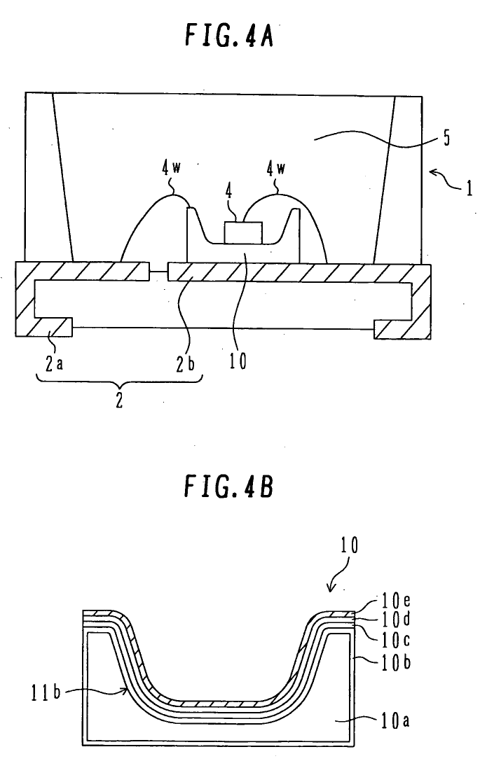

FIGS. 4A and 4B show another example of the structure of an LED package. FIG. 4A shows an LED package mounting a semiconductor light emitting diode chip 4 by using a silicon submount 10 with a horn (concavity). As shown in FIG. 4A, the structure is almost the same as that using the flat plate type silicon submount 3. The silicon submount 10 with a horn is die-bonded to one of leads. Thin film lamination such as shown in FIG. 4B is formed on the upper surface of the silicon submount 10 with the horn. The semiconductor light emitting diode chip 4 is die-bonded to the bottom of the horn of the silicon submount 10 to electrically and mechanically connect the lower surface of the semiconductor light emitting diode chip 4 to the metal film on the silicon submount 10. The metal film on the surface of the silicon submount 10 electrically connected to the lower surface of the semiconductor light emitting diode chip 4 is wire-bonded to the lead that is not die-bonding the silicon submount 10. The upper surface of the semiconductor chip 4 is wire-bonded to the lead that is die-bonding the silicon submount 10. The inner space of the resin housing 1 is filled with resin which is transparent or contains phosphor, to finish the LED package.

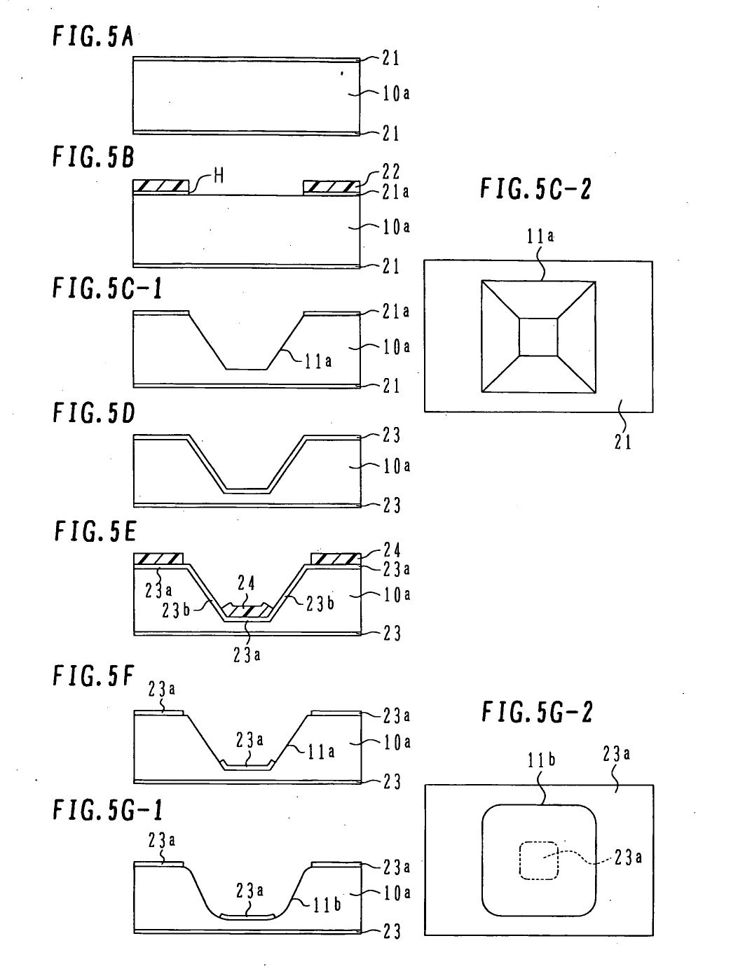

FIG. 4B is a cross sectional view of the silicon submount 10. A (100) silicon substrate 10a is used as a substrate for forming the silicon submount 10. The surface of the silicon substrate 3a is planarized by optical polishing. First, a horn 11b is formed in the silicon substrate 10a. Forming the horn will be later detailed with reference to FIGS. 5A to 5G-2. A silicon dioxide film 10b as an insulating film is formed on the whole surface of the silicon substrate 10a by thermal oxidation in a diffusion furnace. The silicon dioxide film 10b ensures electrical insulation between the silicon submount 10 and lead 2b even if the silicon submount is die-bonded to the lead. Next, similar to forming the flat plate type silicon submount 3, a metal lamination layer is formed on the upper surface of the silicon substrate 10a covered with the silicon dioxide film 10b.

An adhesion layer 10c made of at least one of Ti and Cr is formed on the silicon substrate 10a covered with the silicon dioxide film 10b to provide for solid adhesion to the silicon dioxide film 10b. A barrier metal layer 10d for diffusion prevention made of at least one of Ni, Pt, and Pd is formed on the adhesion layer 10c. A silver alloy layer 10e as a reflection and electrode layer is formed on the barrier metal layer 10d. These layers are formed by sputtering or vapor deposition.

FIGS. 5A to 5G-2 illustrate processes of forming the horn in the silicon substrate 10a.

First, as shown in FIG. 5A, a silicon dioxide film 21 is formed on the surface of the (100) plane silicon substrate 10a, for example, by thermal oxidation in a diffusion furnace.

Next, as shown in FIG. 5B, a resist pattern 22 is formed on the silicon dioxide film 21 by photolithography, the resist pattern having a rectangular opening having a side in a [110] direction. The silicon dioxide film 21 on the bottom of the opening is etched and removed by buffered hydrofluoric acid (hereinafter represented by BHF) to form a silicon dioxide film pattern 21a having an opening H.

As shown in FIG. 5C-1, the resist pattern 22 is removed. By using the silicon dioxide film pattern 21a as a mask, the silicon substrate 10a is anisotropically etched by using, for example, tetramethylammonium hydroxide (hereinafter abbreviated to TMAH). In this embodiment, since the surface of the silicon substrate 10a has the (100) plane, a horn 11a can be formed in the silicon substrate 10a by anisotropic etching. The shape of the horn is a trapezoid in its vertical cross section and a square in its horizontal cross section. In other words, the horn 11a (downwardly narrowing recess) is defined by a bottom surface having the (100) plane and four slanted side walls of the (111) plane. The slanted side wall having the (111) plane has an inclination angle of 54.7° relative to the bottom surface having the (100) plane.

As shown in the plan view of FIG. 5C-2, the horn 1 la has sharply defined corners at borders between four slanted side wall surfaces and one bottom surface.

As shown in FIG. 5D, the silicon dioxide film 21 and silicon dioxide film pattern 21a are removed. Then, a silicon dioxide film 23 is re-formed on the whole surface of the silicon substrate 10a by thermal oxidation.

As shown in FIG. 5E, a resist pattern 24 is formed on the (100) plane. First, a resist is coated on the upper surface of the silicon dioxide film 23 by resist spray coating. Similar to usual photolithography process, the resist spray coating can coat a uniform thickness resist even on a three-dimensional shape having a step of several hundred μm. The resist is exposed by a mask aligner to form a latent pattern of the exposed portions, and the resist on the slanted surfaces of the horn is removed by a development process to thereby form the resist pattern 24.

The silicon dioxide film 23b in the region where the resist pattern 24 is not formed is removed with a BHF solution. As the resist pattern 24 is removed with remover liquid, as shown in FIG. 5F, hard masks of the silicon dioxide film 23a are left on the (100) surface of the silicon substrate 10a. Here, in consideration of over-etch of isotropic etching to be performed later, a portion of the silicon dioxide film is left on the slanted side wall near the bottom surface, and a portion of the silicon dioxide film on the upper surface near the slanted side wall is removed. As shown in FIG. 5G-1, the slanted side walls of the horn 11a are isotropically etched by using fluoric nitric acid (mixture of fluoric acid and nitric acid) so as to round the corners of the horn 11a. As a result, as shown in the plan view of FIG. 5G-2, a horn 11b can be formed which has no sharply defined corners at borders between four slanted side wall surfaces and the bottom surface.

The silicon dioxide film 23 and 23a are removed to finish the silicon substrate 10a as the substrate for the silicon submount 10.

Although the silicon dioxide films are used as the hard masks for isotropic etching, a resist film may be used as a mask.

Instead of liquid-phase etching in the isotropic etching process, isotropic dry etching may be performed such as plasma etching using SF₆ gas as the etchant and reactive ion etching. Similar to the liquid-phase etching, instead of or in addition to a silicon dioxide film, a resist film may be used as the mask for such isotropic etching.

In the above example, all the borders between the surfaces of the horn 11b are rounded. Alternatively, depending on design needs, the sharp corner may be partially left intact on some of the borders. For example, the sharp sides defining the bottom surfaces may be left unrounded, or the corners on the border between adjacent slanted surfaces may be left unrounded.

Evaluation was conducted on a distribution pattern of light emitted when a power was supplied to the finished LED package. Since the corners of the horn 11b are rounded and sharp corners are not formed, dark lines, which would appear due to the sharp corners, are not observed and the optical distribution characteristics become more uniform than conventional cases.

Detailed description will be made on a silver alloy layer according to an embodiment of the present invention. An Ag—Bi based alloy may be used as the silver alloy.

Durability tests were conducted for two kinds of samples of an Ag—Bi (0.07 atomic %, 0.14 atomic %)—neodymium (Nd) (0.2 atomic %) film (film thickness 0.1 μm). Both samples contain Ag at 99 atomic % or more. Measurements were conducted by using an n & k analyzer manufactured by n & k Technology, Inc. (USA) and an n & k method which is a patented technology (refer to A. R. Forouhi and I. Bloomer, Method and Apparatus for Determining Optical Constants of Materials; U.S. Pat. No. 4,905,170; 1990).

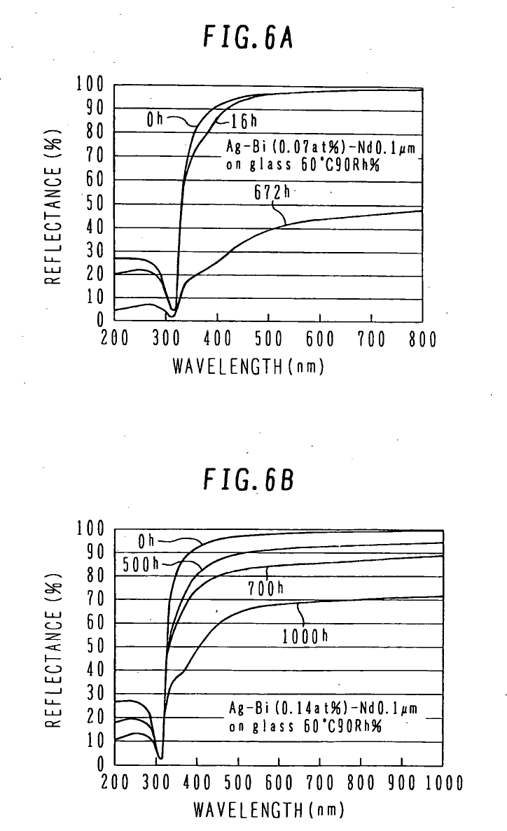

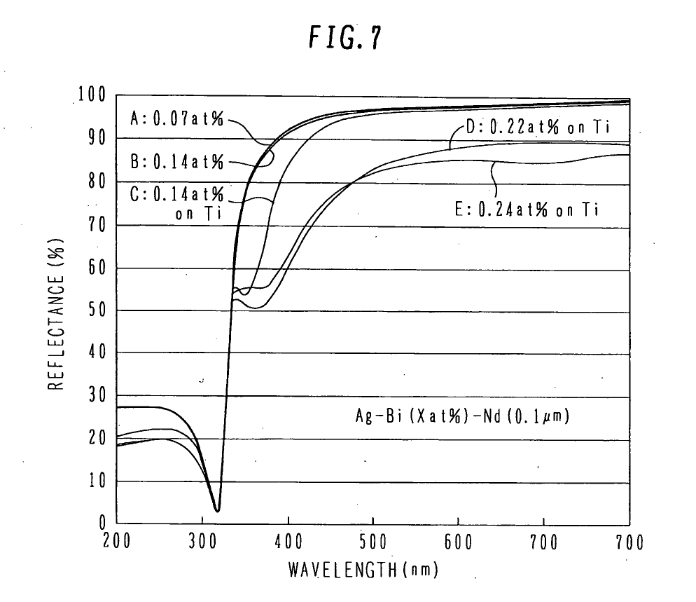

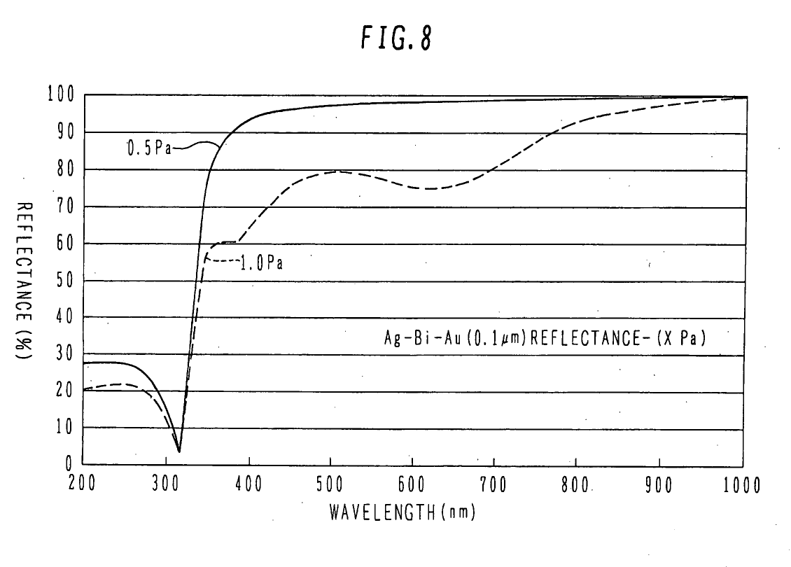

FIG. 6A shows vertical reflectances of Ag—Bi (0.07 atomic %)—Nd (0.2 atomic %) relative to a lapsed time. FIG. 6B shows vertical reflectances of Ag—Bi (0.14 atomic %)—Nd (0.2 atomic %) relative to a lapsed time. As shown in FIGS. 6A and 6B, there is a tendency that the reflectance shows a minimum value near at a wavelength of 320 nm, increases abruptly as the wavelength becomes long, and gradually saturates. In FIG. 6A, saturation reflectances lower to 50% or lower after the lapse of 672 hours. In FIG. 6B, a saturation reflectance is about 70% even after a lapse of 1000 hours. It has been found that durability becomes better as the content of Bi in Ag becomes larger.

The following experiments were conducted in order to find a preferable content of Bi. The following five kinds of films are formed by sputtering on glass substrates by changing target material. The thickness of every sample was set to 0.1 μm. A Nd content was 0.2 atomic % in every sample.

Sample A:

Ag—Bi—Nd alloy film (Bi atomic %=0.07)

Sample B:

Ag—Bi—Nd alloy film (Bi atomic %=0.14)

Sample C:

Ti/Ag—Bi—Nd alloy film (Bi atomic %=0.14, Ti film thickness=0.05 μm)

Sample D:

Ti/Ag—Bi—Nd alloy film (Bi atomic %=0.22, Ti film thickness=0.05 μm)

Sample E:

Ti/Ag—Bi—Nd alloy film (Bi atomic %=0.24, Ti film thickness=0.05 μm)

Initial vertical reflectances of five samples with five kinds of alloy films were measured with an n & k analyzer.

FIG. 7 is a graph showing initial reflectances of the five samples. As shown in FIG. 7, there is a little difference in initial reflectance between sample A and sample B. As seen from the reflectances of samples C, D and E, as the Bi content increases, the initial vertical reflectance lowers. It has been found that the Bi content is preferably set to about 0.14 atomic % or lower in order to use the alloy film as a reflection film.

It has been found from the above-described two types of experiments that if the Bi content is set in the range of 0.07 atomic % to 0.14 atomic %, the initial reflectance can be maintained as high as practically usable as an LED package and durability can be retained. By considering influences and the like by various process parameters, it is considered that the Bi content of a silver alloy layer of a semiconductor light emitting device is preferably in the range of about 0.05 atomic % to about 0.15 atomic %.

Nd is doped to the samples at 0.2 atomic %. Further, studies were performed on atomic elements that can be added to Ag—Bi based alloy which contains Bi in the above-described preferable range. The resulting initial reflectance and durability exhibited desired results even when adding at least one of Au, Pd, copper (Cu), Pt and rare earth elements such as Nd at atomic % larger than that of Bi. In case of at least one of additional elements Au, Pd, Cu, Pt, a total addition amount is preferably about 0.5 to about 5.0 atomic %, and more preferably, about 1.0 to about 2.0 atomic %. In this case, the Ag content is 94 atomic % or more.

While in case of at least one of additional elements Nd and other rare earth elements, a total addition amount is preferably about 0.1 to about 1.0 atomic %, and more preferably, about 0.1 to about 0.5 atomic %. In this case, the Ag content is 98 atomic % or more.

FIG. 8 is a graph showing a dependency of a reflectance of an Ag—Bi based alloy film upon the pressure during film formation. The graph of FIG. 8 shows the dependency when an Ag—Bi—Au (film thickness of 0.1 μm) is formed on a silicon substrate. The vertical axis represents a reflectance and the horizontal axis represents optical wavelength. At a film formation pressure of 0.5 Pa during film formation, a reflectance is near 100% in the visible range, whereas at 1 Pa, a reflectance lowers as the wavelength shortens, even in the visible range. It is therefore preferable that the pressure during film formation is lower than at least 1 Pa.

Therefore, it is preferable to form a silver alloy layer under a condition that the pressure during film formation is lower than about 1 Pa. A film thickness is preferably about 0.1 μm to about 0.6 μm.

Next, description will be made on a thickness range and film formation condition of a barrier metal layer. For example, if Ni is used as the material of the barrier metal layer, a film thickness of Ni is preferably set such that it can perform the function of preventing diffusion of solder to be used for die bonding and at the same time perform the function of maintaining the high reflectance of the Ag—Bi based alloy.

The following experiments were conducted to study a minimum film thickness required to prevent solder diffusion. First, the following layers were sequentially formed in the order from the bottom on a silicon wafer formed with a silicon dioxide film.

Ti (thickness of 0.1 μm)/Ni (thickness of 0.5 μm)/Ag—Bi—Nd (thickness of 0.1 μm)

Zinc free solder of Ag—Sn—Cu was potted on this lamination film and thereafter melted in a reflow furnace. In this case, a diffusion depth of zinc free solder into the Ni barrier layer was observed with a secondary ion mass spectrometer (SIMS).

It has been found from the observation result that a diffusion depth is about 0.5 μm. It is therefore preferable to set a thickness of the Ni film to about 0.5 μm or thicker.

Similar experiments were conducted for Au—Sn eutectic. It has been found that it is sufficient if the Ni layer has a thickness of about 0.1 μm or thicker.

Next, the following experiments were conducted to study a film thickness range capable of maintaining a high reflectance. Metal films having three different thicknesses of Ni were formed on silicon wafers each formed with a silicon dioxide film, and the vertical reflectance of each sample was measured with an n & k analyzer.

Samples:

Ti (thickness of 0.1 μm)/Ni (thicknesses of 0.1 μm, 0.5 μm and 2 μm)/Ag—Bi—Nd (thickness of 0.1 μm)

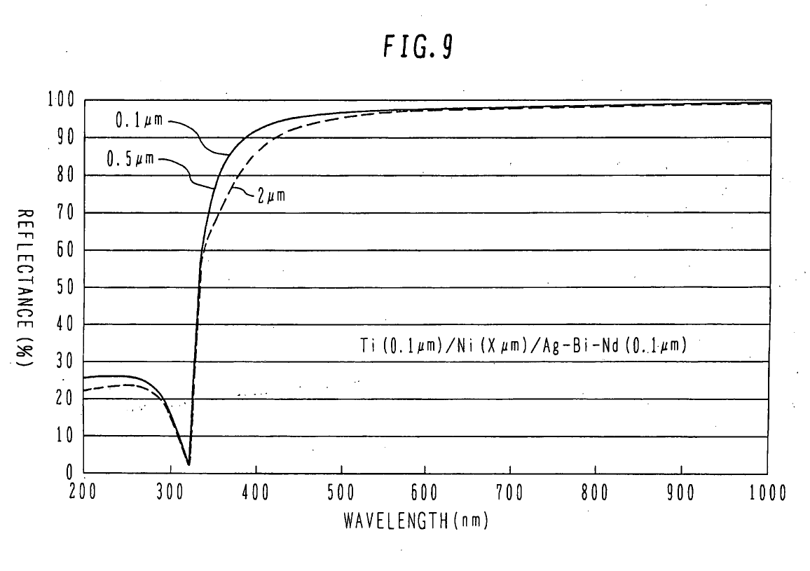

FIG. 9 is a graph showing reflectances of three kinds of samples. As shown in FIG. 9, it has been found that although the reflectance hardly changes between Ni of 0.1 μm and Ni of 0.5 μm, the reflectance in the shorter wavelength range lowers for Ni of 2 μm.

If a red or green LED is used for an LED chip, the film thickness of Ni may be 2 μm. However, by considering use in the short wavelength range, it has been found that the film thickness is preferably thinner than about 2 μm.

It has been therefore found from the experiments that a preferable thickness range of the Ni layer is about 0.1 to about 2 μm.

Next, description will be made on a film forming pressure condition during Ni film formation. The following experiments were conducted to study the pressure condition.

The following metal films were formed by sputtering on a silicon wafer formed with a silicon dioxide film at argon pressures of 0.2 Pa and 1.0 Pa as Ni film forming conditions. The vertical reflectance of each sample was measured with an n & k analyzer. Sample: Ti (film thickness of 0.1 μm)/(Ni (film thickness of 0.2 μm)/Ag—Bi—Au (film thickness of 0.1 μm)

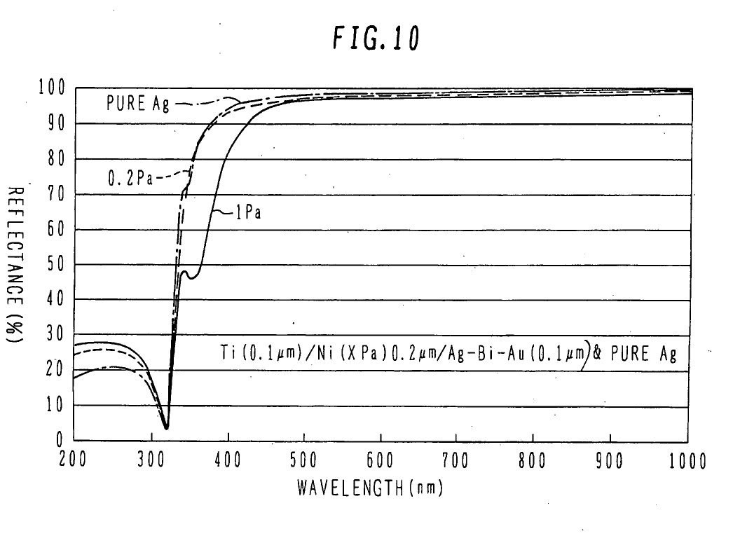

FIG. 10 is a graph showing vertical reflectances of the samples. For comparison, a vertical reflectance of pure silver is also shown. As shown in FIG. 10, at the argon pressure of 0.2 Pa, the film has a reflectance approximately equal to that of pure silver. At the argon pressure of 1 Pa, a reflectance lowers at 400 nm or shorter. However, a reflectance is 90% or higher in the wavelength range of 450 nm to 1000 nm and the film can be used as a reflection film. A preferred argon pressure range for Ni film formation is therefore about 0.2 Pa to about 1 Pa.

The barrier metal layer formed in this manner improves reliability of the silver alloy layer at high temperature and in high humidity. In order to confirm this effect, two films were formed on silicon substrates, one being a lamination film of Ti (0.05 μm)/Ag—Bi—Nd (0.1 μm) and the other being a lamination film of Ti (0.05 μm)/Ni (2 μm)/Ag—Bi—Nd (0.1 μm). A relation between the lapsed time and changes in reflectance was measured by maintaining the films at 6° C. at a relative humidity (RH) of 90%.

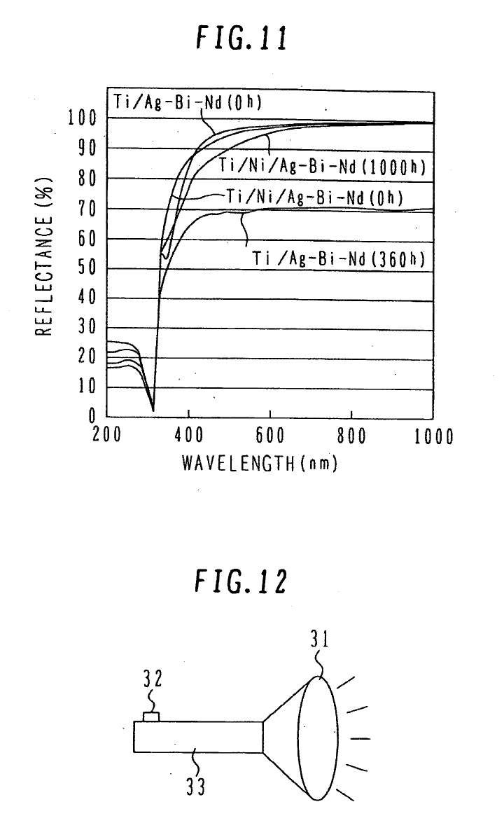

FIG. 11 is a graph showing reflectances of Ag alloy layers formed under the above-described film forming condition. Immediately after the measurements, each reflectance was 95% or higher in the wavelength range of 500 to 1000 nm. The film without the Ni layer lowered its reflectance to about 70% after the lapse of 360 hours. In contrast, the film with the Ni layer maintained its reflectance at 90% or higher even after the lapse of 1000 hours.

Next, description will be made on the thickness range and film forming condition of the adhesion layer. For example, Ti is used as the material of the adhesion layer. The following experiments were conducted to study a Ti film thickness capable of preventing peel-off of the barrier metal (Ni) layer and silver alloy layer from the silicon substrate.

The following two kinds of metal films were formed by sputtering on silicon wafers each formed with a silicon dioxide film, at film forming pressures of 0.5 Pa and 1 Pa, respectively, during film formation. Peeling tests were performed for each sample by using Scotch tapes.

Ti (0.05 μm)/Ni (0.5 μm)/Ag—Bi—Nd (0.1 μm)

At the pressure of 0.5 Pa during Ti film formation, the metal film was peeled off. However, at the pressure of 1 Pa, it was not peeled off.

Peeling tests were performed by changing the thickness of the Ni layer of the metal film to 2 μm and setting the pressure of Ti film formation to 1 Pa. In this case, the metal film was peeled off. However, when the Ti film thickness was increased to 0.1 μmin this sample, the metal film was not peeled off.

It has been found from the above results that it is preferable to set a film thickness of the Ti adhesion layer to about 0.05 μm or thicker and to set the film formation pressure during Ti film formation by sputtering to a pressure higher than 0.5 Pa. Considering the surface roughness, the Ti film formation pressure is preferably set to about 1 Pa or lower.

Lastly, description will be made on surface roughness Ra of the barrier metal layer and silver alloy layer. Ra is also important as a factor influencing the reflectance. It is preferable that Ra of the barrier metal layer is about 5.0 nm or smaller and Ra of the silver alloy layer is about 2.0 nm or smaller. This range is satisfied by the surface roughness of the films formed under the above-described film forming conditions.

As described above, the present inventors have developed suitable combinations of an Ag alloy layer, a barrier metal layer, and an adhesion layer which can prevent film peel-off during die bonding and which can maintain a high reflectance as a reflection film for a wide optical spectrum. With the developments by the inventors, it becomes possible to realize an Ag—Bi based alloy based reflector configuration that is excellent as a reflection film and that can also be used as the material of an electrode (if desired), for semiconductor light emitting devices. Accordingly, a silicon package can be realized having an optical output efficiency higher than conventional LED packages by as much as 30% to 50% or more. Since this package has good thermal conductivity as well as a high reflectance, excellent characteristics can exhibit also for power LED packages that have a high power consumption in the order of 1 W or greater. Furthermore, since the barrier metal layer and adhesion layer are adopted to enhance high durability of Ag—Bi based alloy, it is possible to provide an LED package which has less deterioration of the reflection film to be caused by temporal changes and which is very stable in practical use.

An LED package formed by the method described above can be used with various light emitting devices. For example, the LED package can be used in the manner illustrated in FIG. 12. An LED package is disposed in an LED luminous body 31, and power supply to the LED package is controlled by a switch 32. The LED luminous body 31 can be directed toward a desired target by holding a handle 33.

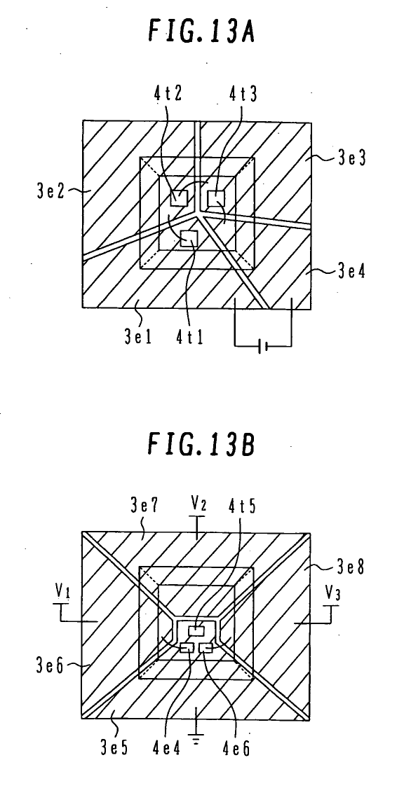

The present invention has been described in connection with the preferred embodiments. The invention is not limited to the above embodiments. FIGS. 13A and 13B are plan views showing examples of other structures of a semiconductor light emitting device. In a mount method illustrated in FIG. 13A, a silver alloy layer 3e is divided into a plurality of areas 3e1, 3e2, 3e3 and 3e4. LED chips 4t1, 4t2 and 4t3 are mounted on the silver alloy layers 3e1, 3e2 and 3e3, respectively, to serially connect the chips. Specifically, lower electrodes of the LED chips 4t1, 4t2 and 4t3 are die-bonded to the silver alloy layers 3e1, 3e2 and 3e3, respectively, to realize electric and mechanical bonding. Next, upper electrodes of the LED chips 4t1, 4t2 and 4t3 are wire-bonded to the silver alloy layers 3e2, 3e3 and 3e4 by using wires of gold or the like, respectively, to realize electric bonding. The silver alloy layers 3e1 and 3e4 are connected to an external power source to form a circuit which applies a forward bias to the LED chips 4t1, 4t2 and 4t3. Resin is molded in the horn mounting the LED chips to finish a semiconductor light emitting device.

By supplying power to three LED chips 4t1, 4t2 and 4t3 at the same time, which can be configured to have different color spectra, respectively, the device can be configured to emit white light as a mixture of RGB optical emissions. Therefore, it is possible to provide a white LED light emitting device that has less absorption and scattering as compared with the case of using wavelength conversion material such as phosphors for white emission, thereby providing a white LED light emitting device having a high optical output efficiency. In another layout of three LED chips, as shown in FIG. 13B, one silver alloy layer 3e5 among four divided silver alloy layers 3e5, 3e6, 3e7 and 3e8 is grounded, and three LED chips 4t4, 4t5 and 4t6 are disposed on the silver alloy layer 3e5 on the horn bottom surface. Electrodes on the bottoms of the LED chips 4t4, 4t5 and 4t6 are mechanically and electrically die-bonded to the silver alloy layer 3e5.

Electrodes on the top surfaces of three LED chips 4t4, 4t5 and 4t6 are wire-bonded to the silver alloy layers 3e6, 3e7 and 3e8, respectively, by wires of gold or the like to realize parallel connection of the LED chips 4t4, 4t5, and 4t6. Resin is molded in the horn mounting the LED chips to finish an LED package.

Voltages of V₁, V₂ and V₃ are applied to the silver alloy layers 3e6, 3e7 and 3e8 to supply power to three LED chips 4t4, 4t5 and 4t6 having different operation voltages. Also in this LED chip mount layout, white light emission can occur as mixture of RGB optical emissions, with less absorption and scattering as compared with the case of using wavelength conversion material such as phosphors for white emission, thereby realizing a high optical output efficiency. Further, since voltage can be applied independently for RGB LED chips, various emission spectrum and color can be selectively realized.

The structures shown in FIGS. 13A and 13B are also described in Japanese Application Nos. JP-2005-347443 and JP-2006-204833, the entire contents of which are herein incorporated by reference.

It is not limited that the semiconductor light emitting device chip be mounted on the silver alloy layer. For example, the semiconductor light emitting device chip may be mounted on an insulating layer, and electrodes and the semiconductor light emitting device chip are wire-bonded. In this case, the silver alloy layer only functions as the reflection film.

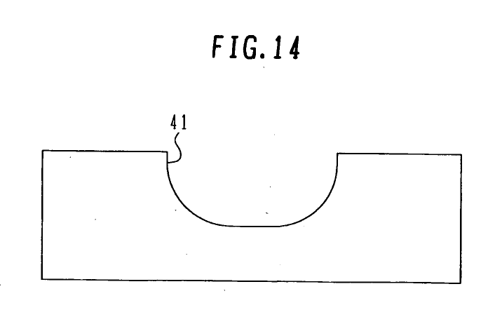

The shape of the concavity (horn) of a silicon substrate is not limited to those described above. FIG. 14 is a cross sectional view showing another example of the concavity of a silicon substrate. A horn 41 formed by isotropic etching has a shape such as shown in FIG. 14. Furthermore, depending on design needs, the horn 11a, shown in FIG. 5c-2, having the slanted side wall of the (111) plane and non-rounded corners may be used.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What we claimed are:

1. A semiconductor light emitting device comprising:
a silicon substrate;
one or more silver alloy portions each constituting a silver alloy layer formed over said silicon substrate; and
a semiconductor light emitting diode chip electrically connected to said silver alloy portion,
wherein said silver alloy portion forms a reflection surface.

2. The semiconductor light emitting device according to claim 1, wherein said silver alloy layer is made of alloy containing bismuth (Bi) at about 0.05 atomic % to about 0.15 atomic %.

3. The semiconductor light emitting device according to claim 2, wherein said silver alloy layer includes at least one of gold (Au), palladium (Pd), copper (Cu), platinum (Pt) and neodymium (Nd), a total amount of which in at atomic % is larger than an amount of Bi in said silver alloy layer in atomic %.

4. The semiconductor light emitting device according to claim 1, wherein said silicon substrate includes a concavity for LED mounting.

5. The semiconductor light emitting device according to claim 4, wherein:
said concavity includes a bottom surface of a (100) plane and a slanted side wall surface of (111) plane formed through anisotropic etching; and
said semiconductor light emitting diode chip is mounted on said bottom surface and said silver alloy layer is formed at least on said slanted side wall surface.

6. The semiconductor light emitting device according to claim 5, wherein said concavity has a rounded corner.

7. The semiconductor light emitting device according to claim 2, wherein said silicon substrate has a concavity for LED mounting.

8. The semiconductor light emitting device according to claim 7, wherein:
said concavity includes a bottom surface of a (100) plane and a slanted side wall surface of (111) plane formed through anisotropic etching; and
said semiconductor light emitting diode chip is mounted on said bottom surface and said silver alloy layer is formed at least on said slanted side wall surface.

9. The semiconductor light emitting device according to claim 8, wherein said concavity has a rounded corner.

10. The semiconductor light emitting device according to claim 1, further comprising:
an insulating film formed on a surface of said silicon substrate;
an adhesion layer made of at least one of titanium (Ti) and chromium (Cr) and formed on said insulating film; and
a barrier metal layer made of at least one of nickel (Ni), Pt and Pd and formed on said adhesion layer,
wherein said silver alloy layer is formed on said barrier metal layer.

11. The semiconductor light emitting device according to claim 10, wherein a surface roughness Ra of said barrier metal layer is about 5.0 nm or smaller and a surface roughness of said silver alloy layer is about 2.0 nm or smaller.

12. The semiconductor light emitting device according to claim 10, wherein a thickness of said adhesion layer is about 0.05 μm or thicker, a thickness of said barrier metal layer is about 0.1 μm to about 2.0 μm and a thickness of said silver alloy layer is about 0.1 μm to about 0.6 μm.

13. A manufacture method for a semiconductor light emitting device comprising steps of:
(a) forming an insulating film on a surface of a silicon substrate;
(b) forming an adhesion layer made of at least one of Ti and Cr on said insulating film;
(c) forming a barrier metal layer made of at least one of Ni, Pt and Pd on said adhesion layer;
(d) forming one or more silver alloy portions each constituting a silver alloy layer on said barrier metal layer; and
(e) electrically connecting at least one of said silver alloy portions to a semiconductor light emitting device chip.

14. The manufacture method for a semiconductor light emitting device according to claim 13, wherein:
said step (a) comprises steps of:
(a-1) forming a concavity for LED mounting in said silicon substrate; and
(a-2) forming an insulating film on a surface of said silicon substrate formed with said concavity.

15. The manufacture method for a semiconductor light emitting device according to claim 14, wherein said step (a-1) comprises forming said concavity in said silicon substrate through anisotropic etching, said concavity having a bottom surface of a (100) plane and four slanted side wall surfaces of a (111) plane.

16. The manufacture method for a semiconductor light emitting device according to claim 15, further comprising, between said steps (a-1) and (a-2), a step of etching an interior of said concavity to round corners of said concavity that have been formed by said slanted side wall surfaces and said bottom surface.

17. The manufacture method for a semiconductor light emitting device according to claim 13, wherein said adhesion layer, said barrier metal layer and said silver alloy layer are formed by sputtering or vacuum vapor deposition at respective film forming pressures that are lower than about 1 Pa.

18. A light emitting apparatus, comprising:
a light emitting device that emits light;
a substrate;
an adhesion layer on a surface of said substrate, the adhesion layer including at least one of titanium (Ti) and chromium (Cr);
a barrier layer on the adhesion layer, the barrier layer including at least one of nickel (Ni), platinum (Pt), and palladium (Pd); and
a reflection layer on the barrier layer to reflect at least a portion of said light emitted by said light emitting device, the reflection layer including silver (Ag) in an amount of about 98 atomic % or more, bismuth (Bi) in an amount of about 0.05 atomic % to about 0.15 atomic %, and neodymium (Nd) in an amount of about 0.1 atomic % to about 1.0 atomic %.

19. The light emitting apparatus according to claim 18, wherein said substrate is made of silicon and includes a silicon oxide surface, and
wherein said adhesion layer is formed on the silicon oxide surface.

20. The light emitting apparatus according to claim 18, wherein said substrate includes a concavity that is provided with said adhesive layer, said barrier layer, and said reflection layer thereon, and
wherein said light emitting device is mounted on a portion of said reflection layer at a bottom of the concavity by solder bonding.

21. The light emitting apparatus according to claim 18, wherein said adhesive layer is made of Ti at a thickness of about 0.05 μm or thicker,
wherein said barrier layer is made of Ni at a thickness of about 0.1 μm to about 2 μm, and
wherein said reflection layer is about 0.1 μm to about 0.6 μmin thickness
